(19) United States
(12) Patent Application Publication
(10) Pub. No.: US 2022/0285303 A1
(43) Pub. Date: Sep. 8, 2022

(54) CONTACT STRUCTURES FOR DIRECT BONDING

(71) Applicant: INVENSAS BONDING TECHNOLOGIES, INC., San Jose, CA (US)

(72) Inventors: Laura Wills Mirkarimi, Sunol, CA (US); Cyprian Emeka Uzoh, San Jose, CA (US)

(21) Appl. No.: 17/684,841

(22) Filed: Mar. 2, 2022

Related U.S. Application Data
(60) Provisional application No. 63/156,290, filed on Mar. 3, 2021.

(51) Int. Cl. H01L 23/00

(52) U.S. Cl. CPC H01L 24/08; H01L 24/05; H01L 2224/05647; H01L 2224/08145; H01L 2224/08225; H01L 2224/05541; H01L 24/03; H01L 2224/03013; H01L 24/80; H01L 2224/80001; H01L 2224/03462; H01L 2924/37001

(57) ABSTRACT

A bonded structure is disclosed. The bonded structure can include a first element that includes a first conductive feature and a first nonconductive region. The first conductive feature can include a fine grain metal that has an average grain size of 500 nm or less. The bonded structure can include a second element that includes a second conductive feature and a second nonconductive region. The first conductive feature is directly bonded to the second conductive feature without an intervening adhesive, and the second nonconductive region is directly bonded to the second nonconductive region without an intervening adhesive.

### CROSS-REFERENCE TO RELATED APPLICATIONS

This application claims priority to U.S. Provisional Patent Application No. 63/156,290, filed Mar. 3, 2021, titled “CONTACT STRUCTURES FOR DIRECT BONDING,” the entire contents of each of which are hereby incorporated herein by reference.

### BACKGROUND

### Field

The field relates to contact structures for direct bonding.

### Description of the Related Art

Semiconductor elements, such as semiconductor wafers, can be stacked and directly bonded to one another without an adhesive. For example, in some hybrid direct bonded structures, nonconductive field regions of the elements can be directly bonded to one another, and corresponding conductive contact structures can be directly bonded to one another. In some applications, it can be challenging to create reliable electrical connections between opposing contact pads. Accordingly, there remains a continuing need for improved contact structures for direct bonding.

### BRIEF DESCRIPTION OF THE DRAWINGS

Specific implementations will now be described with reference to the following drawings, which are provided by way of example, and not limitation.

FIG. 1A is a schematic cross sectional side view of a structure in an intermediate stage in forming a first element.

FIG. 1B is a schematic cross section side view of the first element before bonding.

FIG. 2 is a schematic cross sectional side view of a bonded structure that includes the first element and a second element.

FIG. 3 is a schematic top plan view of coarse grain copper showing grains of coarse grain copper.

FIG. 4 is a schematic top plan view of fine grain copper showing grains of fine grain copper, according to an embodiment.

FIG. 5 is a graph showing relationships between a temperature and a mean resistance of a fine grain copper pad and a conventional copper pad.

FIG. 6A is a schematic cross sectional side view of a bonded structure.

FIG. 6B is a schematic cross sectional side view of a bonded structure according to an embodiment.

FIG. 6C is a schematic cross sectional side view of a bonded structure according to another embodiment.

FIG. 6D is a schematic cross sectional side view of a bonded structure according to another embodiment.

FIG. 7A is a top-down electron back-scatter diffraction (EBSD) image of a conventional or coarse grain copper pad.

FIG. 7B is a top-down EBSD image of a nano-twin copper pad.

FIG. 7C is a top-down EBSD image of a fine grain copper pad according to an embodiment.

### DETAILED DESCRIPTION

The present disclosure describes methods of directly bonding conductive pads in electronic elements using engineered metallic grain structures. Such grain engineering can be advantageous for direct metal bonding, such as direct hybrid bonding. For example, two or more semiconductor elements (such as integrated device dies, wafers, etc.) may be stacked on or bonded to one another to form a bonded structure. Conductive contact pads of one element may be electrically connected to corresponding conductive contact pads of another element. Any suitable number of elements can be stacked in the bonded structure. The methods and bond pad structures described herein can be useful in other contexts as well.

In some embodiments, the elements are directly bonded to one another without an adhesive. In various embodiments, a non-conductive (e.g., semiconductor or inorganic dielectric) material of a first element can be directly bonded to a corresponding non-conductive (e.g., semiconductor or inorganic dielectric) field region of a second element without an adhesive. In various embodiments, a conductive region (e.g., a metal pad or contact structure) of the first element can be directly bonded to a corresponding conductive region (e.g., a metal pad or contact structure) of the second element without an adhesive. The non-conductive material can be referred to as a nonconductive bonding region or bonding layer of the first element. In some embodiments, the non-conductive material of the first element can be directly bonded to the corresponding non-conductive material of the second element using bonding techniques without an adhesive using the direct bonding techniques disclosed at least in U.S. Pat. Nos. 9,564,414; 9,391,143; and 10,434,749, the entire contents of each of which are incorporated by reference herein in their entirety and for all purposes. Additional examples of hybrid bonding may be found throughout U.S. Pat. No. 11,056,390, the entire contents of which are incorporated by reference herein in their entirety and for all purposes. In other applications, in a bonded structure, a non-conductive material of a first element can be directly bonded to a conductive material of a second element, such that a conductive material of the first element is intimately mated with a non-conductive material of the second element. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SICOH, silicon carbonitride or diamond-like carbon or a material comprising of a diamond surface. Such carbon-containing ceramic materials can be considered inorganic, despite the inclusion of carbon.

In various embodiments, direct bonds can be formed without an intervening adhesive. For example, semiconductor or dielectric bonding surfaces can be polished to a high degree of smoothness. The bonding surfaces can be cleaned and exposed to a plasma and/or etchants to activate the surfaces. In some embodiments, the surfaces can be terminated with a species after activation or during activation (e.g., during the plasma and/or etch processes). Without being limited by theory, in some embodiments, the activation process can be performed to break chemical bonds at the bonding surface, and the termination process can provide additional chemical species at the bonding surface that improves the bonding energy during direct bonding. In some embodiments, the activation and termination are provided in the same step, e.g., a plasma or wet etchant to activate and terminate the surfaces. In other embodiments, the bonding surface can be terminated in a separate treatment to provide the additional species for direct bonding. In various embodiments, the terminating species can comprise nitrogen. Further, in some embodiments, the bonding surfaces can be exposed to fluorine. For example, there may be one or multiple fluorine peaks near layer and/or bonding interfaces, particularly dielectric bonding interfaces. Thus, in the directly bonded structures, the bonding interface between two non-conductive materials can comprise a very smooth interface with higher nitrogen content and/or fluorine peaks at the bonding interface. Additional examples of activation and/or termination treatments may be found throughout U.S. Pat. Nos. 9,564,414; 9,391,143; and 10,434,749, the entire contents of each of which are incorporated by reference herein in their entirety and for all purposes.

In various embodiments, conductive contact pads of the first element can also be directly bonded to corresponding conductive contact pads of the second element. For example, a direct hybrid bonding technique can be used to provide conductor-to-conductor direct bonds along a bonding interface that includes covalently direct bonded dielectric-to-dielectric surfaces, prepared as described above. In various embodiments, the conductor-to-conductor (e.g., contact pad to contact pad) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes. The bond structures described herein can also be useful for direct metal bonding without non-conductive region bonding, or for other bonding techniques.

In some embodiments, inorganic dielectric bonding surfaces can be prepared and directly bonded to one another without an intervening adhesive as explained above. Conductive contact pads (which may be surrounded by nonconductive dielectric field regions) may also directly bond to one another without an intervening adhesive. In some embodiments, the respective contact pads can be recessed below exterior (e.g., upper) surfaces of the dielectric field or nonconductive bonding regions, for example, recessed by less than 30 nm, less than 20 nm, less than 15 nm, or less than 10 nm, for example, recessed in a range of 2 nm to 20 nm, or in a range of 4 nm to 10 nm. The coefficient of thermal expansion (CTE) of the dielectric material may range between 0.1 ppm/° C. and 5 ppm/° C. for example and the CTE of the conductive material may range from 6 ppm/° C. and 40 ppm/° C., or between 8 ppm/° C. and 30 ppm/° C. The differences in the CTE of the dielectric material and the CTE of the conductive material restrain the conductive material from expanding laterally at subsequent thermal treating operations. The nonconductive bonding regions can be directly bonded to one another without an adhesive at room temperature in some embodiments and, subsequently, the bonded structure can be annealed. Upon annealing, the contact pads can expand with respect to the nonconductive bonding regions and contact one another to form a metal-to-metal direct bond. Beneficially, the use of hybrid bonding techniques, such as Direct Bond Interconnect, or DBI®, available commercially from Xperi of San Jose, Calif., can enable high density of pads connected across the direct bonding interface (e.g., small or fine pitches for regular arrays). In various embodiments, the conductive feature (e.g., the contact pads) can comprise copper, although other metals may be suitable. Thus, when copper is used as the material of the conductive feature in this disclosure, copper is an example of the material of the conductive feature, and other suitable metals may be implemented.

Thus, in direct bonding processes, a first element can be directly bonded to a second element without an intervening adhesive. In some arrangements, the first element can comprise a singulated element, such as a singulated integrated device die. In other arrangements, the first element can comprise a carrier or substrate (e.g., a wafer) that includes a plurality (e.g., tens, hundreds, or more) of device regions that, when singulated, form a plurality of integrated device dies. Similarly, the second element can comprise a singulated element, such as a singulated integrated device die. In other arrangements, the second element can comprise a carrier or substrate (e.g., a wafer). In some embodiments, the singulated element may comprise a direct or indirect band gap semiconductor material. In some embodiments, multiple dies having different CTEs may be bonded on the same carrier. In some embodiments, the CTE of the substrate of the bonded die is similar to the CTE of the substrate of the carrier. In other embodiments the CTE of the substrate of the bonded die is different from the CTE of the substrate of the carrier. The difference in CTEs between bonded dies or between bonded dies and the carrier may range between 1 ppm/° C. and 70 ppm/° C. and less than 30 ppm/° C., for example, less than 12 ppm/° C.

As explained herein, the first and second elements can be directly bonded to one another without an adhesive, which is different from a deposition process. The first and second elements can accordingly comprise non-deposited elements. Further, directly bonded structures, unlike deposited layers, can include a defect region along the bonding interface in which nanovoids are present. The nanovoids may be formed due to activation of the bonding surfaces (e.g., exposure to a plasma). As explained above, the bonding interface can include concentration of materials from the activation and/or last chemical treatment processes. For example, in embodiments that utilize a nitrogen plasma for activation, a nitrogen peak can be formed at the bonding interface. In embodiments that utilize an oxygen plasma for activation, an oxygen peak or oxygen rich layer can be formed at the bonding interface. In some embodiments, the bonding interface can comprise a nitrogen-terminated inorganic non-conductive material, such as nitrogen-terminated silicon, silicon oxide, silicon nitride, silicon oxynitride, silicon carbide, silicon oxycarbide, silicon oxycarbonitride, etc. Thus, the surface of the bonding layer can comprise silicon nitride, silicon oxynitride, silicon oxycarbonitride, or silicon carbonitride, with levels of nitrogen present at the bonding interface that are indicative of nitrogen termination of at least one of the elements prior to direct bonding. Other than nitrogen-containing dielectrics, the nitrogen content of the non-conductive material typically has a gradient peaking at or near the surface. In some embodiments, nitrogen and nitrogen related moieties may not be present at the bonding interface. As explained herein, the direct bond can comprise a covalent bond, which is stronger than van Der Waals bonds. The bonding layers can also comprise polished surfaces that are planarized to a high degree of smoothness.

A grain size of a conductive feature can affect the propensity of the conductive feature to bond at comparatively lower temperature, and bonding strength between the bonded conductive features. In general, the grain sizes near the bonding interface can be observed on a surface of the conductive feature (before bonding) or in a cross-sectional view of the conductive feature. As one goal is to allow grain boundaries of the conductive features on opposite elements to intersect one another and facilitate mobility and thus direct bonding, grain size may be measured relative to the lateral size of the conductive feature to be bonded. The conductive feature can comprise a metal feature, such as a copper contact pad or line. A conductive feature with relatively small grains can be energetically unstable, and the small grains compared to larger grains can grow to larger grains with much lower thermal budget for a given isothermal anneal condition or lower temperature for given times. Therefore, the conductive features with relatively small gain sizes can bond to one another with a relatively high bonding strength even with minimal application of heat, and lower anneal temperatures can be achieved for direct bonding with relative small grain sizes. The bonding strength between such conductive features with relatively small grain sizes is greater than a bonding strength between single crystal or large grain conductive features for a given anneal temperature. Excessive impurities within the grain and/or at grain boundaries can inhibit or impede the grain growth.

The conductive features can comprise fine grain metal plated films, such as fine grain copper plated films. Fine grain copper plated films are films which have an average grain size of 50 nm to 500 nm, for example, an average grain size in a range of 10 nm to 500 nm, in a range of 10 nm to 300 nm, in a range of 10 nm to 150 nm, in a range of 10 nm to 100 nm, in a range of 10 nm to 75 nm, or in a range of 10 nm to 50 nm. Standard back end of the line copper plated films in integrated circuits today have an average grain size that ranges from 1 μm to 10 μm. A number of grains in a conductive feature can depend at least in part on the feature size of the conductive feature. For example, when a feature size of a standard copper conductive feature is 0.5 μm, the standard copper conductive feature includes 1-3 grains at a bonding interface. When a feature size of the fine grain metal conductive feature is 0.5 μm, the fine grain metal conductive feature can include 5 to 10 times more grains than the 0.5 μm standard copper conductive feature.

The fastest diffusivity path for atoms of conductive features can depend on the temperature, the nature microstructure, microstructural defects, hardness, grain size, impurity content of the film, film stress, interfacial adhesion, surface mobility of the atoms and more. Lattice diffusion can have the highest activation energy about 2 ev for copper, for example. The activation energy for diffusion along grain boundaries and interfaces is significantly lower (e.g., about 0.7 eV for Cu as an example) than activation energy of lattice diffusion. Therefore, lattice diffusion can be the slowest path for atomic mass transport and the grain-boundary diffusion can be the fastest diffusivity paths for atomic mass transport, in some embodiments. Also, the activation energy for copper creep can be similar to the value of grain-boundary diffusion. Additionally, the creep rate can vary inversely to the cube of the grain size.

Smaller grains, on the account of their sizes, can have far more grain boundary surface area than larger grains. The grain boundary surface area of a small grain conductive feature may be more than 10 times, more than 50 times, more than 250 times, or more than 1000 times greater than the grain boundary surface area of a large grain conductive feature. The conductive feature with relatively small grains can have a higher creep rate than a conductive feature with relatively large or coarse grains. The higher creep rate can contribute to higher propensity for bonding compared to a lower creep rate. The relatively small grains can be referred to as fine grains. For example, grains having a maximum width of less than 10 nm, less than 50 nm, less than 100 nm, less than 300 nm, or less than 500 nm can be defined as fine grains. Coarse grains can typically have 1 μm to 2 μm or larger in their maximum width. The higher creep rate of fine grains and relatively large grain boundary surface area of the fine grains that can contribute to relatively large diffusion paths with low activation energies can be particularly beneficial in a relatively small conductive feature or structure, such as a microstructure with a maximum dimension less than 5 μm (e.g., 1 μm),because such structures can be bonded at lower temperatures as compared to structures with conductive feature having large grains. The conductive features, such as bonding pads, vias (e.g., TSVs), traces, or through substrate electrodes of embodiments described herein can have a maximum lateral dimension in a range between about 0.01 μm and 25 μm, between about 0.1 μm and 10 μm, between about 0.5 μm and 8 μm, between about 2 μm and 5 μm, between about 1 μm and 3 μm, or between about 0.01 μm and 1 μm. An example of a relatively small bond pad, for example, can have an entire exposed area or a bonded conductive area of the conductive feature at the bonding interface that is smaller than about 100 μm², smaller than 50 μm² smaller than 20 μm², smaller than 10 μm² and smaller than 2 μm².

In various embodiments, the metal-to-metal bonds between the contact pads can be joined such that conductive material grains, for example copper grains, grow into each other across the bonding interface. In some embodiments, the copper can have grains oriented vertically along the 111 crystal plane for improved copper diffusion across the bonding interface. In some embodiments, however, other copper crystal planes can be oriented vertically relative to the contact pad surface. The nonconductive bonding interface can extend substantially entirely to at least a portion of the bonded contact pads, such that there is substantially no gap between the nonconductive bonding regions at or near the bonded contact pads. In some embodiments, having the fine grain directly bonded interconnect, very small voids may nucleate along the bonding interface or in proximity to the bonding interface. The width of a void at a cross section of a bonding interface or close to the bonding interface of the conductive features of bonded elements, can be, for example, less than 5%, less than 1%, or less than 0.1% of the width of the cross section. In some embodiments, a barrier layer may be provided under the contact pads (e.g., which may include copper). In other embodiments, however, there may be no barrier layer under the contact pads, for example, as described in U.S. Pat. No. 11,195,748, which is incorporated by reference herein in its entirety and for all purposes.

Annealing temperatures and annealing durations for forming the metal-to-metal direct bond or thermal budget is of great importance in the fabrication of directly bonded components. Ideally, it can be preferable to bond elements with very similar CTE or small difference in their CTEs, to minimize CTE mismatch related stress upon cool down from bonding temperature to room temperature. Assuming a proper adhesion between bonded elements, the CTE related stress in the bonded elements can be proportional to the bonding temperature and to the difference between the CTEs of the individual elements in the bonded structure. A higher bonding temperature can cause a greater CTE related stress. Analogously, a greater CTE difference between the elements can cause a greater CTE related stress. A high stress in bonded structures can be undesirable because it may induce defects such as microcrack, delamination, and/or high warpage in the bonded elements or a stack of elements. To directly bond two elements each having a non-conductive bonding surface and a conductive bonding region, the opposing non-conduction bonding surfaces can be bonded, for example, at temperatures lower than 120° C. The opposing conductive bonding regions can be bonded at bonding temperatures in a range between 250° C. and 450° C., and the bonding duration can be in a range between 15 minutes and 6 hours. In some circumstances, the bonding duration can be more than 6 hours. When the bonding temperature is higher, the bonding duration may be shorter in some applications. In general, when a higher bonding temperature is used, there may be a greater chance of causing defects in the bonded structure. From the foregoing, methods for forming direct a conductive to conductive (e.g., metal to metal) bond at comparatively lower temperatures can be desirable.

In some embodiments, in the direct bonding of two substrates having a CTE difference of between the elements, it may be desirable to lower the annealing temperature and/or annealing duration to minimize consumption of the thermal (energy) budget. Various embodiments disclosed herein can create contact structures (e.g., copper contact pads) that have fine copper grains, e.g., with average grain sizes of 500 nm or less, 350 nm or less, 300 nm or less, or 50 nm or less, such as in a range of 10 nm to 500 nm, in a range of 10 nm to 300 nm, in a range of 10 nm to 150 nm, in a range of 10 nm to 100 nm, in a range of 10 nm to 75 nm, or in a range of 10 nm to 50 nm. The use of a fine grain metal (e.g., fine grain copper or nano copper) for the conductive structures can beneficially provide a high potential energy and a high creep rate such that a lower thermal budget can be used for the annealing process that creates the conductive-to-conductive (e.g., copper-to-copper) direct bond connections. Moreover, the increased potential energy can improve interdiffusion at the copper-to-copper interface and strong metallurgical bonds. Fine grain copper can also have a more uniform pre-bonding recess across the wafer due to the small sizes of the grains than coarse grain copper. The fine grain copper may be easier to control the recess uniformly than coarse grain copper, because when a pad is formed with coarse grain copper, the pad might have different behavior within the pad, which can affect the polish rate. Subsequent wet and/or dry etch chemistry may not substantially disrupt the uniformity of recess sizes across the wafer, which can improve electrical yield after bonding.

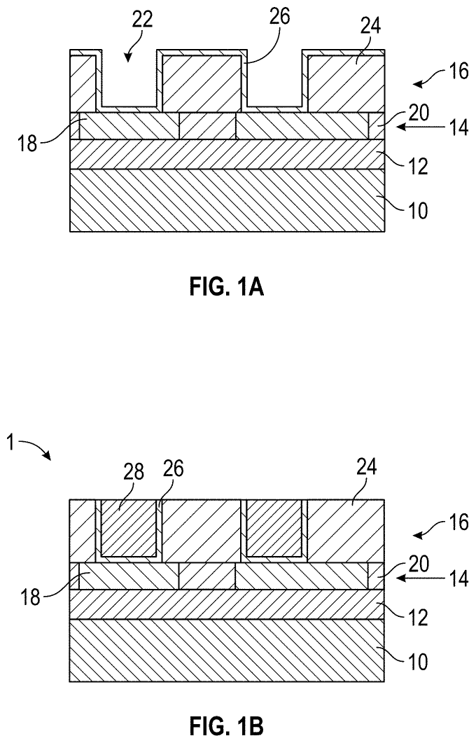

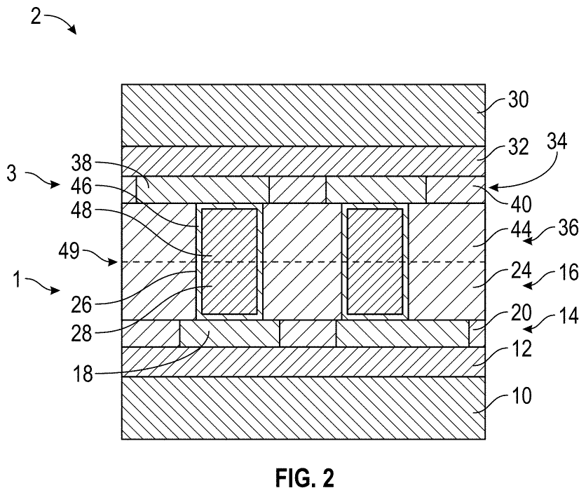

FIG. 1A is a schematic cross sectional side view of a structure in an intermediate stage in forming an element (a first element 1). FIG. 1B is a schematic cross section side view of the element 1. FIG. 2 is a schematic cross sectional side view of a bonded structure 2 that includes the first element 1 and a second element 3. In some embodiments, the first and second elements 1, 3 can have the same or generally similar structures. In some embodiments, the first and second elements 1, 3 can comprise semiconductor elements.

The first element 1 can include a carrier 10, an isolation layer 12 over the carrier 10, a metallization layer 14 over the isolation layer 12, and a bonding layer 16 over the metallization layer 14. In some embodiments, the carrier 10 can comprise a substrate (e.g., a wafer) that includes a device region. In some embodiments, the carrier 10 can comprise a device layer or structure. In some embodiments, the isolation layer 12 can comprise an oxide layer that is deposited on the carrier 10. The oxide layer can have a thickness of about 0.3 μm. For example, the thickness of the oxide layer can be in a range of 0.1 μm to 20 μm, or 0.1 μm to 10 μm. In some embodiments, the isolation layer 12 may comprise multiple dielectric layers comprising embedded interconnected conductive features (not shown). The embedded conductive features of the isolation layer 12 can be connected to a conductive portions of the metallization layer 14. In some embodiments, the isolation layer 12 comprises the metallization layer 14 and/or the bonding layer 16. In some applications, a planar top surface of the isolation layer 12 may comprise the bonding surface.

The metallization layer 14 can comprise a conductive portion 18 and a nonconductive portion 20. In some embodiments, the metallization layer 14 can comprise a back end of the line (BEOL) metallization layer. In some embodiments, the conductive portion 18 can comprise conductive traces that extend laterally and/or conductive vias that extend vertically within the metallization layer 14 to function as a redistribution layer (RDL). The conductive portion 18 can comprise any suitable conductive material, such as copper (Cu). The copper can be formed by a conventional copper plating process. In some embodiments, the metallization layer 14 can define a bottom surface of a cavity 22 formed in the bonding layer 16.

In some embodiments, the bonding layer 16 can comprise nonconductive layer that can define a nonconductive region 24, a barrier layer 26 disposed in the cavity 22, and a conductive feature 28 over the barrier layer 26 and disposed in the cavity 22. The conductive feature 28 can comprise a contact structure configured to contact and electrically connect to an opposing contact structure on another element. A thickness of the conductive feature 28 may vary in a range of, for example, 0.3μ to 6μ, and typically in a range of 0.5μ to 4μ. Similarly, a width of the conductive features 28 may range in a range of, for example, 0.3μ to 60μ, 0.5μ to 40μ, or 0.5μ to 20μ. As described herein, the conductive feature 28 may comprise a contact pad, trace, via, or any suitable combinations thereof. In some embodiments, the via may comprise a thru-substrate electrode. A width of the thru-substrate conductive feature at the bonding surface may vary in a range of, for example, 1μ to 50μ, 2∞ to 30μ, or 2.5μ to 15μ. The conductive feature 28 and the metallization layer 14 can be electrically connected to one another. In some embodiments, the barrier layer 26 can be disposed between the conductive feature 28 and the metallization layer 14. Thus, in the illustrated embodiment, the conductive feature 28 comprises a contact pad disposed over a metallization layer (such as a BEOL layer). In other arrangements, the conductive feature 28 can comprise a conductive via extending through (or mostly through) the element as in through substrate electrode or through element electrode or thru-silicon-vias TSV in the case of silicon substrate.

The nonconductive region 24 can comprise a dielectric layer. In some embodiments, the nonconductive region 24 may comprise multiple layers of different dielectric materials. For example, the nonconductive region 24 can comprise silicon oxide. As shown in FIG. 1A, the cavity 22 can be formed in the nonconductive region 24. The cavity 22 can extend at least partially through a thickness of the nonconductive region 24. For example, the cavity 22 can extend completely through the thickness of the nonconductive region 24.

In some embodiments, the barrier layer 26 can comprise a diffusion barrier layer that prevents or reduces diffusion of the material of the conductive feature 28 into the nonconductive region 24. In some embodiments, the barrier layer 26 can comprise tantalum, titanium, cobalt, nickel or tungsten or any suitable compound or combinations thereof. In some embodiments, the barrier layer 26 can comprise a multi-layer structure.

In some embodiments, the conductive feature 28 can comprise copper (Cu). For example, the conductive feature 28 can comprise a fine grain metal (e.g., fine grain copper). The fine grain metal or bonding pad can be defined as a metal feature with microstructure, having an average grain width less than 20 nm, less than 50 nm, less than 100 nm, less than 300 nm, or less than 500 nm. For example, the maximum width of the fine grain metal can be in a range of 10 nm to 500 nm, in a range of 10 nm to 300 nm, in a range of 20 nm to 500 nm, 20 nm to 300 nm, 20 nm to 100 nm, 20 nm to 50 nm, 50 nm to 500 nm, 50 nm to 300 nm, or 100 nm to 300 nm within the microstructure. A size variation within the conductive feature 28 can be within about 10% among 95% or more of the grains in the conductive feature 28. In some embodiments, an average grain size of the grains in the conductive feature 28 can be less than 100 nm, less than 300 nm, or less than 500 nm. The grains of the fine grain metal can be notably smaller than a coarse grain metal that includes coarse grains such as grains with 1 μm to 2 μm or larger in their maximum width. In some embodiments, the fine grain metal may have higher stress than the coarse grain metal due to how the fine grain metal is deposited. The fine grain metal can have higher potential energy than the coarse grain metal.

In some embodiments, the conductive feature 28 can be provided into the cavity 22 by way of plating. The conductive feature 28 can be deposited under a high various plating current density in a suitable plating bath. For example, the plating current density may range from 1 mA/cm² to 70 mA/cm², or 40 mA/cm² to 70 mA/cm² by direct current (DC) or pulse plating, or a combination of the two. For example, the conductive feature 28 can be electroplated at a current density in a range of 1 mA/cm² to 70 mA/cm² for a time in a range of 0.5 seconds to 5 seconds at lower current densities, and 0.3 seconds to 2 seconds at higher current densities. In some embodiments, the conductive feature 28 can comprise a metal coating that can be formed by coating copper from acid copper bath or copper fluoroborate bath, copper sulfonic acid bath, or copper pyrophosphate plating bath. In some embodiments, the acid plating bath can comprise 0.1M to 0.4M of copper ions, 0.1M to 1M of acid (e.g., 0.3M to 0.6M of organic or inorganic acid), and 30 ppm to 70 ppm of halide ions. In some embodiments, refining agents can be used in a plating process for reducing the grain size of the conductive feature 28. The grain refining agents can comprise thiourea, thiazine (sulfur bearing group), oxazine, or oxazine dyes. A concentration of the grain refiner used in the plating process can be in a range of, for example, 2 mg/L to 70 mg/L, 2 mg/L to 50 mg/L, 2 mg/L to 20 mg/L, 10 mg/L to 70 mg/L, or 20 mg/L to 50 mg/L. A smaller the grain size of the conductive feature 28 can be provided with a higher concentration of the grain refiner.

The fine grain metal can comprise a relatively high concentration of impurities (e.g., interstitial and non-interstitial impurities). The impurities can include, for example, sulfur, carbon, nitrogen, phosphorus, or the like. Typically, the concentration of impurities can be greater than 30 ppm, or greater than 50 ppm and preferably less than 5000 ppm. In some embodiments, a relatively small concentration of impurities can be desired.

In some embodiments, the conductive feature 28 can comprise constituents. The constituents are additives that can be added during the plating process or formation of a seed layer in order to promote the formation of the fine grains in the conductive feature 28. In some embodiments, an average grain size of the fine grains in the conductive feature 28 can be 100 nm or less, 300 nm or less, or 500 nm or less. The constituents can comprise boron, indium, phosphorous, gallium, nickel, cobalt, tin, manganese, titanium, vanadium or selenium. In some embodiments, an amount of the constituents in the conductive feature 28 at grain boundaries can be less than 0.5% or less than 0.1% of the conductive feature 28.

In some embodiments, the conductive feature 28 can comprise nanoparticles of an inert material, such as, for example, silicon oxide, aluminum, or titanium oxide, which may be co-plated into the fine grain metal of the conductive feature 28. The inert material is a material that does not primarily form an alloy with the fine grain metal of the conductive feature 28 at an annealing temperature of 400° C. or less. In some embodiments, more than 90%, more than 95%, or more than 99% of the nanoparticles of the inert material do not form an alloy with the fine grain metal of the conductive feature 28. The nanoparticles can be present at grain boundaries in the conductive feature 28 and sub-grain boundaries of the coated metal of the conductive feature 28. The nanoparticles can suppress grain growth of the grains in the conductive feature 28 at temperature below about 120° C. A concentration of the nanoparticles in the conductive feature 28 can be controlled such that the nanoparticles do not significantly alter the conductivity of the conductive feature 28. For example, the concentration of the nanoparticles can be less than 1% or less than 0.1% of the conductive feature 28.

In some embodiments, the plating can be conducted at a low temperature, such as, for example, 5° C. to 15° C., or lower than 20° C. The resulting conductive feature 28 formed at the low temperature can tend to grow more quickly than that formed at a room temperature. In some embodiments, the conductive feature 28 formed at the low temperature that includes low impurities, for example, less than 30 ppm, may be stored at low temperatures preferably below 10° C. to suppress grain growth, and can be further processed (e.g., chemical-mechanical polishing (CMP)) at the low temperature. The conductive feature 28 formed at the low temperature can be cleaned and bonded, for example, within 8 hours after the CMP process or within 4 hours.

In some embodiments, after the metal is plated in any suitable processes disclosed herein, the metal can be annealed to at least partially stabilize the microstructure of the metal which can be referred to as a grain recovery process. The annealing can take place before a CMP process. In some embodiments, the metal can be annealed at a temperature in a range of 80° C. to 150° C. For example, the metal can be annealed for a duration of 60 to 120 minutes. The grain sizes of the grains in the metal before and after the annealing process to initiate grain recovery process are generally smaller than microstructure of the stabilized metal. Typically, the expected change in size of the grains is less than 10%, compared to conventional BEOL or packaging copper where the difference in the as plated and as annealed grain sizes is typically greater than 50% and even greater than 100%.

As shown in FIG. 2, the first element 1 can be bonded to the second element 3. The second element 3 can comprise a carrier 30, an isolation layer 32 over the carrier 30, a metallization layer 34 over the isolation layer 32, and a bonding layer 36 over the metallization layer 34. The metallization layer 34 can comprise a conductive portion 38 and a nonconductive portion 40. The bonding layer 36 can comprise a nonconductive region 44, a barrier layer 46 disposed in a cavity 42, and a conductive feature 48 over the barrier layer 46 and disposed in the cavity 42.

In some embodiments, the first element 1 and the second element 3 can be directly bonded to one another without an intervening adhesive along a bonding interface 49. For example, the conductive features (e.g., the conductive feature 28) of the first element 1 can be directly bonded to the corresponding conductive features (e.g., the conductive feature 48) of the second element 3 without an intervening adhesive, and the nonconductive region 24 of the first element 1 can be directly bonded to the nonconductive region 44 of the second element 3 without an intervening adhesive. For example, a bonding process according to an embodiment can include directly bonding the nonconductive region 24 of the first element 1 to the nonconductive region 44 of the second element 3 at room temperature, and directly bonding the conductive feature 28 to the conductive feature 48 by expanding the conductive feature 28 to the conductive feature 48 by way of annealing at a temperature, for example, below 300° C., below 250° C., below 200° C., or below 180° C. The first element 1 and the second element 3 can be directly bonded to one another at a room temperature, typically between 18 to 40° C. For example, the anneal temperature for bonding the conductive feature 28 and the conductive feature 48 can be in a range of 120° C. to 250° C., 120° C. to 200° C., or 120° C. to 180° C. In some embodiments, the conductive feature 28 of the first element 1 and/or the conductive feature 48 of the second element 3 can comprise a recess, and when the nonconductive region 24 and the nonconductive region 44 are bonded, there can be a gap between the conductive feature 28 and the conductive feature 48. The gap or recess can be bridged when the elements 1, 3 are annealed at higher temperature where the metallurgical bond is formed between the two opposing conductive features 28 and 48.

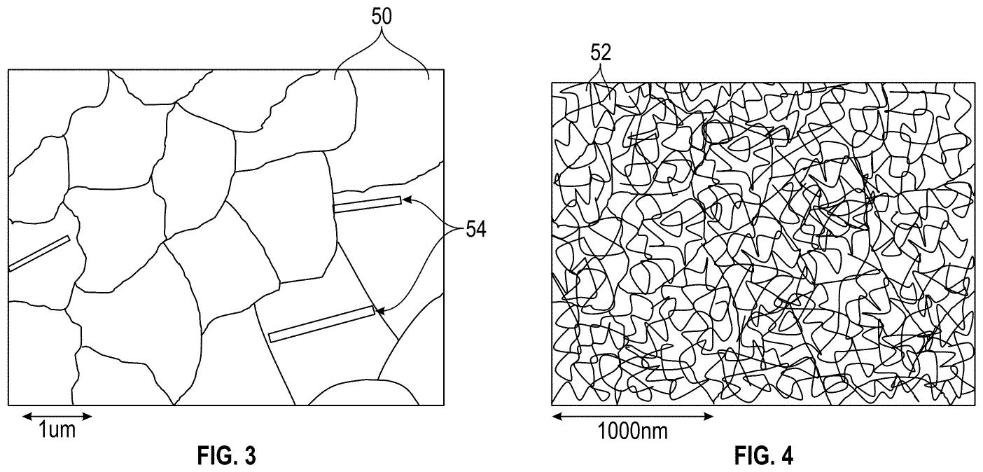

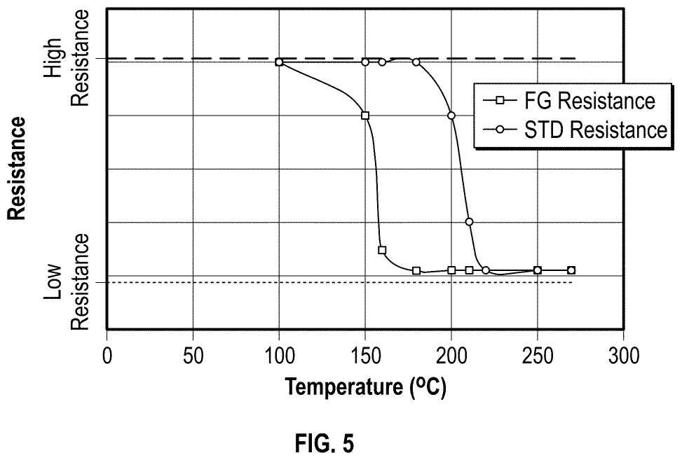

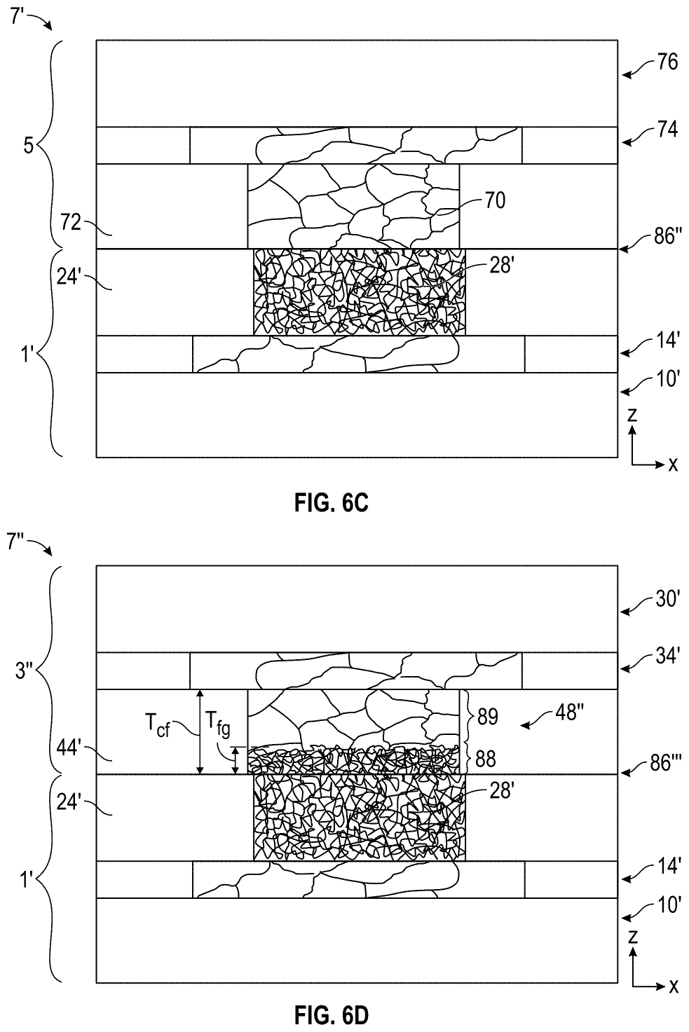

FIG. 3 is a schematic top plan view of coarse grain copper (e.g., conventional copper) showing grains 50 of coarse grain copper. FIG. 4 is a schematic top plan view of fine grain copper showing grains 52 of fine grain copper, according to an embodiment. Both coarse grain copper and fine grain copper of FIGS. 3 and 4 have been annealed at a temperature between 80° C. and 150° C. for 120 minutes. An average grain size of coarse grain copper can range between 0.5 μm and 3 μm, and an average grain size of fine grain copper can range between 10 nm and 500 nm. As shown in FIG. 3, twins 54 may be formed in the grains of copper. In some embodiments, the fine grain copper grains 52 can comprise nano twins (not shown) within the grain structure (e.g., within one or more grains of the grains 52). In some embodiments, the conductive feature 28 of FIG. 1B can comprise more than one type of microstructure. For example, portions of the conductive feature 28 can comprise a top portion and a bottom portion that is positioned closer to the metallization layer 18 than the top portion (see FIG. 6D). In some embodiments, the top portion of the conductive feature 28 has a thickness in a range of 5% to 70% of a thickness of the conductive feature 28. In some embodiments, the top portion of the conductive feature 28 has a thickness in a range of, for example, 50 nm to 500 nm. The bottom portion can comprise a conductive feature with a highly oriented microstructure, for example a nano-twin copper microstructure. The top portion can comprise the bonding surface of the conductive feature 28 and the conductive region between the bonding surface and the bottom portion. The top portion can comprise a fine grain metal, such as, for example, a fine grain copper. In some embodiments, the bottom portion of the conductive feature 28 can comprise a material that has a coarse grain structure, for example conventional BEOL or packaging copper with coarse grains. In some embodiments, the bottom portion can comprise other materials other than pure copper, for example copper alloy, nickel, cobalt, tungsten, aluminum and their various respective alloys. In some applications, a barrier layer (not shown) may be disposed between the top and bottom portion of the conductive feature 28. The barrier layer can prevent or mitigate the mixing of microstructures of the top and bottom portions.

The activation energy for diffusion along grain boundaries and interfaces is significantly lower than the lattice diffusion. For fine grain microstructure, with massive grain boundary surface area, in metal-to-metal bonding, grain-boundary diffusion path is dominant. Also, fine grain microstructure typically can exhibit high creep rate compared to the nano-twined copper and conventional coarse grain copper with significantly larger grain sizes. The significantly high concentration of very fast diffusion paths and higher creep rate in fine grain copper, accounts for its lower temperature bonding propensity. The lower temperature bonding propensity of fine metal microstructures is why this microstructure is desirable at the bonding surface of directly bonded interconnects.

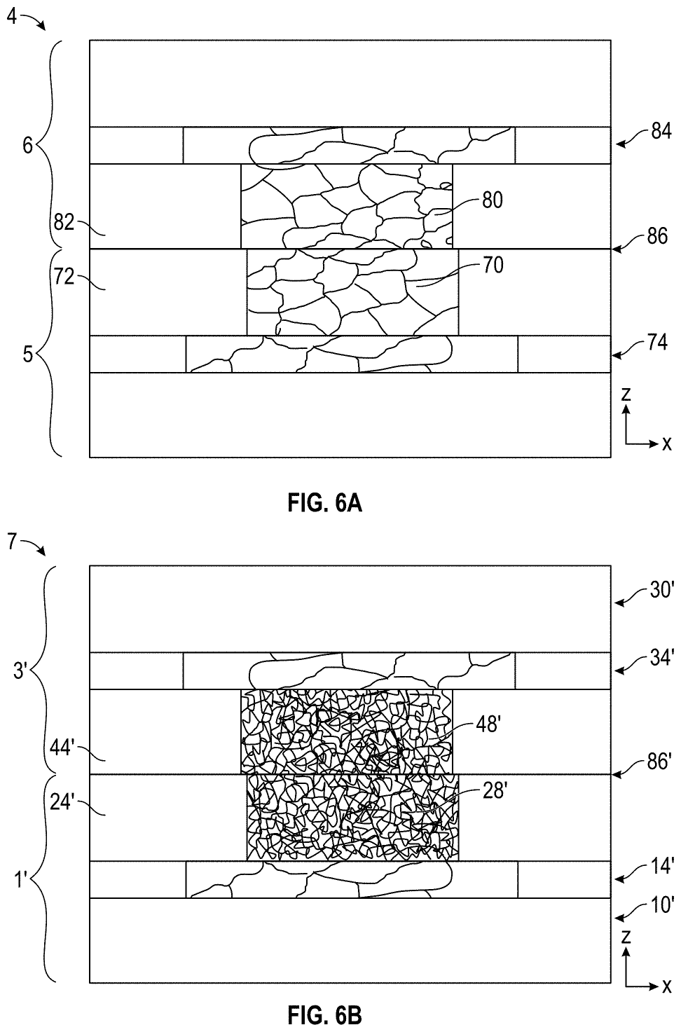

FIG. 5 is a graph showing relationships between a temperature and a mean resistance of a fine grain copper pad (FG) and a conventional copper pad (STD). The mean resistance can provide an indication of the degree of contact between opposing conductive features; a lower mean resistance can mean a better connection as compared to a higher mean resistance. The graph indicates that the fine grain pad reaches the desired value, or book value, of resistance at a lower temperature than the conventional copper pad. The result indicates that the fine grain pad can be bonded to another pad with a lower annealing (bonding) temperature than the conventional copper pad.

FIG. 6A is a schematic cross sectional side view of a bonded structure 4 that includes conductive feature 70, 80 (e.g., conventional copper pads). The bonded structure includes a first element 5 and a second element 6 that is bonded to the first element 5 along a bonding interface 86. The first element 5 comprises the conductive feature 70, a nonconductive region 72, and a metallization layer 74. The second element 6 comprises the conductive feature 80, a nonconductive region 82, and a metallization layer 84. The conductive features 70, 80 comprise coarse grains, for example copper grains having an average grain size greater than 1 micron. The conductive features 74, 84 comprise a conventional, coarse grain metal (e.g., coarse copper).

The bonded structure 4 has been annealed at a temperature higher than 180° C. for bonding. A metal-to-metal (e.g., copper-copper) bonding interface at the bonding interface 86 can develop as the annealing time or temperature increases. After annealing for a longer time, more metal diffusion (e.g., copper diffusion) occurs at the bonding interface. The bonding interface 86 can extend along an x-direction, and a z-direction that is generally perpendicular to the x-direction can be a film growth direction. In some embodiments of the bonded elements 4, the number of grains of the conductive feature 70, 80 intercepting the bonding interface 86, at its maximum width or diameter may be less than 12 grains. Depending on the diameter or width of the conductive feature 70, 80, the number of intercepting grains at the bonding interface may be less than 8 grains or even less than 5 grains.

FIG. 6B is a schematic cross sectional side view of a bonded structures 7 according to an embodiment. Unless otherwise noted, components of FIG. 6B can be the same as or generally similar to the like components of FIGS. 1A-2. The bonded structure 7 can comprise a first element 1′ and a second element 3′ that is bonded to the first element 1′ along a bonding interface 86′. The first element 1′ can comprise a conductive feature 28′, a nonconductive region 24′, a metallization layer 14′, and a carrier 10′. The second element 3′ can comprise of a conductive feature 48′, a nonconductive region 44′, an metallization layer 34′, and a carrier 30′. The conductive features 28′, 48′ can comprise a fine grain metal (e.g., fine grain copper). The metallization layers 24′, 34′ can comprise a conventional, coarse grain metal (e.g., coarse grain copper). In some embodiments of the bonded structures 7, one of the metallization layers 14′ or 34′ may comprise a layer having fine grain metal, such as, for example, fine grain copper.

The bonded structure 7 has been annealed at a temperature of 180° C. for bonding. The grain sizes of the grains in the conductive features 28′, 48′ before and after the annealing process to bond the conductive features 28′, 48′ can be generally similar. For example, an average grain size of the conductive features 28′, 48′ after the annealing process can be no more than 2 times an average grain size of the unannealed conductive features 28′, 48′. A metal-to-metal (e.g., copper-copper) bonding interface at the bonding interface 86′ can develop as the annealing time and/or temperature increases. After annealing for a sufficient time, more metal diffusion (e.g., copper diffusion) can occur at the metal-to-metal bonding interface. In some embodiments, the bonding interface 86′ can extend along an x-direction, and a z-direction that is generally perpendicular to the x-direction can be a film growth direction. In some embodiments, as a result of the fine grain structure of the bonded structure 7, the number of grains of the bonded conductive features 28′ or 48′ intercepting the interface 86′ in a linear lateral dimension, at its maximum width or diameter can be more than 12 grains. The number of grains intercepting the interface 86′ can be more than 16 grains, or more than 20 grains, in some embodiments.

FIG. 6C is a schematic cross sectional side view of a bonded structure 7′ according to an embodiment. Unless otherwise noted, components of FIG. 6C can be the same as or generally similar to the like components of FIGS. 1A-2, 6A, and 6B. The bonded structure 7′ can include a first element 1′ that comprises a conductive feature 28′ directly bonded to a conventional conductive feature 70, such as a conventional copper pad, that includes a coarse grain conductive metal, along a bonding interface 86″. The first element 1′ can comprise the conductive feature 28′, a nonconductive region 24′, a metallization layer 14′, and a carrier 10′. The element 5 can comprise the conductive feature 70, a nonconductive region 72, a metallization layer 84, and a carrier 74. The conductive feature 70 is an example of a conductive feature, and the element 5 can include any suitable conductive feature. The conductive features 28′ can comprise a fine grain metal (e.g., fine grain copper) and the conductive feature 70 can comprise a coarse grain metal (e.g., coarse grain copper). In some embodiments, the material of the conventional conductive feature 70 can be selected based at least in part on the material of the conductive feature 28′. For example, the material of the conventional conductive feature 70 can be selected to have the same or similar type metal as the material of the conductive feature 28′. The metallization layers 14′, 74 can comprise conventional coarse grain copper. Other types of metals and metal microstructures may be used in the metallization layer 14′, 74. In some embodiments of the bonded structures 7′, one of the metallization layers 14′, 74 can comprise a layer having fine grain conductive material, for example fine grain copper.

The bonded structure 7′ has been annealed (e.g., at a temperature of 180° C.) for bonding. The grain sizes of the grains in the conductive features 28′ and the conductive pad70 before and after the annealing process to bond the conductive features 70′, 80, are dissimilar. A metal-to-metal (copper-copper) bonding interface at the bonding interface 86″ can develop as the annealing time and/or temperature increases. After annealing for a sufficient time, more metal diffusion (e.g., copper diffusion) can occur at the bonding interface of the mated conductive feature 28′ and the conductive feature 70. In some embodiments, the bonding interface 86″ can extend along an x-direction, and an z-direction that is generally perpendicular to the x-direction can be a film growth direction. In some embodiments, the number of intercepting grains measured in a linear lateral dimension at the bonding interface 86″ from the first conductive feature 28′ of the first element 1′, at a diameter of the bonding interface 86″ may be more than 10% higher than the number of intercepting grains at the bonding interface 86″ from the conductive feature 70 of the element 5. For example, the bonded structure 7′ can comprise of more than 20 grains intercepting the interface 86″ from the conductive features 28′ and less than 13 grains intercepting the interface 86″ from the conductive feature 80. In some embodiments, the number of grains intercepting the interface 86″ from the first conductive feature 28′ of the first element 1′ is different from the number of grains intercepting the bonding interface 86″ from the conductive feature 80 of the element 5.

FIG. 6C is a schematic cross sectional side view of a bonded structure 7″ according to an embodiment. Unless otherwise noted, components of FIG. 6D can be the same as or generally similar to the like components of FIGS. 1A-2, and 6A-6C. The bonded structure 7″ can be generally similar to the bonded structure 7 of FIG. 6A except that an element 3″ of the bonded structure 7″ comprises a fine grain portion 88 and a coarse grain portion 89 within a conductive feature 48″. Though FIG. 6C illustrates one fine grain portion and one coarse grain portion, there can be a plurality of fine grain portions and/or a plurality of coarse grain portions, in some embodiments. The fine grain portion 88 positioned closer to the bonding interface 86′″ can be referred to as a top portion, and the coarse grain portion 89 closer to the metallization layer 34′ can be referred to as a bottom portion. In some embodiments, the fine grain portion 88 of the conductive feature 48″ has a thickness T_{fg} in a range of 5% to 70% of a thickness T_{cf} of the conductive feature 28. For example, the thickness T_{fg} can be in a range of 5% to 50%, 5% to 20%, 10% to 50%, or 10% to 20% of the thickness T_{cf} of the conductive feature 28. In some embodiments, the thickness T_{fg} of the fine grain portion 88 can be in a range of, for example, 50 nm to 500 nm. For example, the thickness T_{fg} can be in a range of 50 nm to 400 nm, 50 nm to 300 nm, 100 nm to 500 nm, or 100 nm to 300 nm.

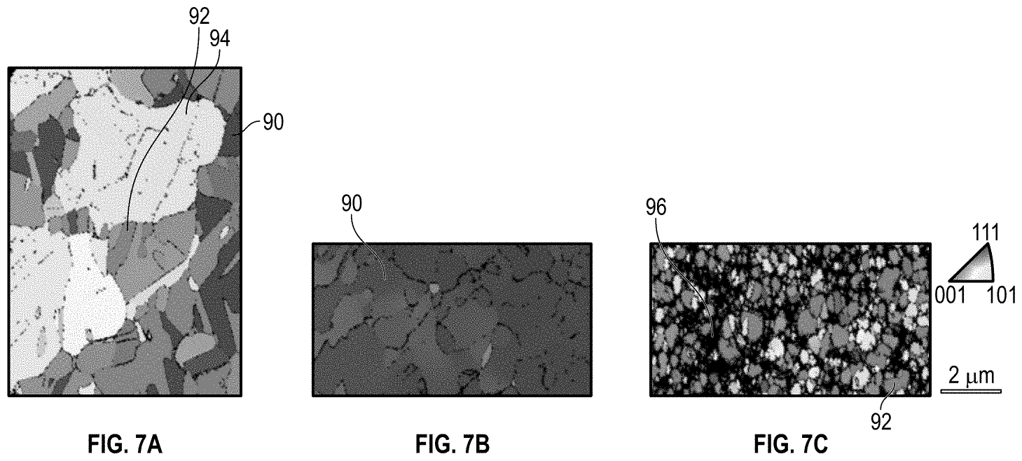

FIGS. 7A-7C show top-down electron back-scatter diffraction (EBSD) images of different types of copper features. FIG. 7A is a top-down EBSD image of a conventional or coarse grain copper feature. FIG. 7B is a top-down EBSD image of a nano-twin copper feature. FIG. 7C is a top-down EBSD image of a fine grain copper feature according to an embodiment. FIGS. 7A-7C show grain orientations parallel to a z-direction (See FIG. 6A-6D) that is in the same direction as a film growth direction (e.g., normal to the image plane in the images of FIGS. 7A-7C). For example, a grain 90 has crystal orientation such that the z-direction is generally parallel to the grain's <111> orientation, a grain 92 has crystal orientation such that the z-direction is generally parallel to the grain's <001> orientation, and a grain 94 has crystal orientation such that the z-direction is generally parallel to the grain's <101> orientation. FIG. 7A shows an example microstructure of the coarse grain copper feature comprising coarse grains with different grain orientations (e.g., the <111>, <001>, and <101> orientations). In contrast, FIG. 7B shows an example microstructure of nano-twin copper feature having highly oriented grains comprising mostly or essentially a single metal grain orientation (e.g., the <111> orientation). In other embodiments, the highly oriented grains may have the <111> orientation, the <100> orientation, the <110> orientation, or their combinations as in bicrystal microstructures and/or highly oriented non-cubic structures, such as tetragonal or hexagonal grain structures. FIG. 7C shows an example microstructure of the fine grain copper feature. The microstructure comprises fine grains, typically with grain sizes less than 100 nm, and the various grains of the fine grains can have different grain orientations, such as the <111>, <110>, <100> orientations. The dark areas in FIG. 7C are grains 96 with orientations that were not detected by electron back scattering diffraction.

In one aspect, a bonded structure is disclosed. The bonded structure can include a first element that include a first conductive feature and a first nonconductive region. The first conductive feature includes a fine grain metal that has an average grain size of 500 nm or less. The bonded structure can include a second element that includes a second conductive feature and a second nonconductive region. The first conductive feature is directly bonded to the second conductive feature without an intervening adhesive, and the second nonconductive region is directly bonded to the second nonconductive region without an intervening adhesive.

In one embodiment, the first conductive feature includes copper.

In one embodiment, the grains of the first conductive feature have a maximum grain size less than 500 nm. The grains of the first conductive feature can have the maximum grain size less than 350 nm. The grains of the first conductive feature can have the maximum grain size less than 50 nm.

In one embodiment, an average grain size of grains of the second conductive feature is 500 nm or less.

In one embodiment, an average grain size of grains of the second conductive feature is more than 1 micron.

In one embodiment, the average grain size of the fine grain metal of the first conductive feature is 350 nm or less. The average grain size of the fine grain metal of the first conductive feature can be in a range of 10 nm to 300 nm.

In one embodiment, more than 95% of the grains of the first conductive feature have a grain size variation less than 10%.

In one embodiment, the first element further comprising a metallization layer that has a conductive portion. The conductive portion of the metallization layer can include a metal that has an average grain size in a range of 1 μm to 2 μm.

In one embodiment, the fine grain metal of the first conductive feature includes nanoparticles of an inert material. A concentration of the nanoparticles can be less than 1% of the first conductive feature. The concentration of the nanoparticles can be less than 0.1% of the first conductive feature. The nanoparticles can include one or more of silicon oxide, alumina, and titanium oxide.

In one embodiment, the fine grain metal includes constituents.

In one aspect, a bonded structure. The bonded structure can include a first element that includes a first conductive feature and a first nonconductive region. The first conductive feature includes a fine grain metal having constituents. The bonded structure can include a second element that includes a second conductive feature and a second nonconductive region. The first conductive feature is directly bonded to the second conductive feature without an intervening adhesive, and the second nonconductive region is directly bonded to the second nonconductive region without an intervening adhesive.

In one embodiment, the constituents include at least one of boron, indium, phosphorus, gallium, nickel, cobalt, tin, manganese, titanium, vanadium and selenium. The first conductive feature can include a fine grain metal that has an average grain size of 500 nm or less. The average grain size of the fine grain metal of the first conductive feature can be in a range of 10 nm to 300 nm.

In one aspect, an interconnect structure is disclosed. The interconnect structure can include an element that includes a bonding surface. The element has a conductive feature and a nonconductive region. The conductive feature is at least partially embedded in the nonconductive region. The conductive feature includes a bottom portion and a top portion disposed over the bottom portion. The top portion positioned closer to the bonding surface of the element than the bottom portion. The top portion has an average grain size smaller than the average grain size of the bottom portion. The average grain size of the top portion is 500 nm or less.

In one embodiment, a bonded structure includes the interconnect structure and a second element.

In one aspect, a method of forming a substrate is disclosed. The method can include providing a cavity in a nonconductive layer of a semiconductor element, providing a conductive contact structure in the cavity, and preparing the nonconductive layer and the conductive contact structure for direct bonding. The conductive contact structure has a fine grain structure that includes an average grain size less than 500 nm.

In one embodiment, the conductive contact structure includes copper.

In one embodiment, the average grain size is less than 350 nm. The average grain size can be in a range of 10 nm to 300 nm.

In one embodiment, providing the conductive contact structure comprises providing a copper electroplating bath that has less than 0.5% additives and electroplating the conductive contact structure into the cavity. The additives include one or more of boron, indium, phosphorus, gallium, nickel, cobalt, tin, manganese, titanium, vanadium and selenium.

In one embodiment, providing the conductive contact structure includes providing a copper electroplating bath having electrically inactive nanoparticles therein. The electrically inactive nanoparticles can include one or more of silicon oxide, alumina, and titanium oxide. A concentration of the nanoparticles can be less than 1% by volume. The concentration of the nanoparticles can be less than 0.1% by volume.

In one embodiment, metal grain recovery of the conductive contact structure is suppressed at room temperature and at temperatures below 120° C.

In one embodiment, providing the conductive contact structure includes electroplating the cavity at a temperature less than 30° C. The method can further include electroplating the cavity at a temperature in a range of 5° C. to 15° C. The method can further include chemical mechanical polishing the nonconductive layer and the conductive contact structure at a temperature in a range of 5° C. to 15° C.

In one embodiment, the method further includes directly bonding the nonconductive layer of the semiconductor element to a second nonconductive layer of a second semiconductor element without an intervening adhesive. The method can further includes annealing the semiconductor element and the second semiconductor element to cause the conductive contact structure to contact a second conductive contact structure of the second semiconductor element. The annealing can be performed at a temperature of less than 300° C. The annealing can be performed at a temperature of less than 250° C.

In one embodiment, providing the conductive contact structure includes electroplating the cavity using a current density in a range of 0.1 mA/cm² to 70 mA/cm².

In one embodiment, providing the conductive contact structure includes providing an electroplating bath having 0.1M to 0.4M of copper ions and 0.1M to 1M of an acid.

In one embodiment, providing the nonconductive layer includes deposition over an integrated circuit device. The method can further include lining at least sidewalls of the cavity with a barrier layer prior to filling the cavity with the conductive contact structure having the fine grain structure.

In one aspect, a method of forming a substrate is disclosed. The method can include providing a cavity in a nonconductive layer of a semiconductor element, providing a conductive contact structure in the cavity, and preparing the nonconductive layer and the conductive contact structure for direct bonding. The conductive contact structure has a fine grain structure.

In one embodiment, the conductive contact structure includes copper.

In one embodiment, a majority of the grains of the conductive contact structure have a size of 500 nm or less. The majority of the grains can have a size of 350 nm or less. The majority of the grains can have a size in a range of 10 nm to 300 nm.

In one embodiment, an average grain size of the grains of the conductive contact structure is 500 nm or less. The average grain size can be 350 nm or less. The average grain size can be in a range of 10 nm to 300 nm.

In one embodiment, providing the conductive contact structure includes providing a copper electroplating bath having less than 0.5% additives and electroplating the conductive contact structure into the cavity. The copper electroplating bath can have less than 0.1% additives. The additives can include one or more of boron, indium, phosphorus, gallium, nickel, cobalt, tin, manganese, titanium, vanadium and selenium.

In one embodiment, providing the conductive contact structure includes providing a copper electroplating bath having electrically inactive nanoparticles therein. The electrically inactive nanoparticles can include one or more of silicon oxide, alumina, and titanium oxide. A concentration of the nanoparticles can be less than 1% by volume. The concentration of the nanoparticles can be less than 0.1% by volume.

In one embodiment, metal grain recovery of the conductive contact structure is suppressed at room temperature and at temperatures below 120° C.

In one embodiment, providing the conductive contact structure includes electroplating the cavity at a temperature less than 30° C. The method can further include electroplating the cavity at a temperature in a range of 5° C. to 15° C. The method can further include chemical mechanical polishing the nonconductive layer and the conductive contact structure at a temperature in a range of 5° C. to 15° C.

In one embodiment, the method further includes directly bonding the nonconductive layer of the semiconductor element to a second nonconductive layer of a second semiconductor element without an intervening adhesive. The method can further include annealing the semiconductor element and the second semiconductor element to cause the conductive contact structure to contact a second conductive contact structure of the second semiconductor element. The annealing can be performed at a temperature of less than 300° C. The annealing can be performed at a temperature of less than 250° C.

In one embodiment, providing the conductive contact structure includes electroplating the cavity using a current density in a range of 0.1 mA/cm² to 70 mA/cm². The current density can be in a range of 40 mA/cm² to 70 mA/cm².

In one embodiment, providing the conductive contact structure includes providing an electroplating bath having 0.1M to 0.4M of copper ions and 0.1M to 1M of an acid. The electroplating bath can have halide ions in a range of 30 ppm to 70 ppm.

In one embodiment, providing the nonconductive layer comprises deposition over an integrated circuit device. The method can further includes lining at least sidewalls of the cavity with a barrier layer prior to filling the cavity with the conductive contact structure having the fine grain structure. The providing the nonconductive layer can include deposition on a redistribution layer over the integrated circuit device.

In one aspect, a bonded structure is disclosed. The bonded structure can include a first element that includes a first conductive feature and a first nonconductive region. The bonded structure can include a second element that includes a second conductive feature and a second nonconductive region. The first conductive feature is directly bonded to the second conductive feature without an intervening adhesive thereby forming a bonding interface. A number of grains at the bonding interface is greater than 40 grains. The second nonconductive region is directly bonded to the second nonconductive region without an intervening adhesive.

In one embodiment, the first conductive feature comprising a fine grain metal having an average grain size of 500 nm or less.

In one embodiment, first conductive feature has a maximum lateral dimension in a range between about 0.01 μm and 25 μm. The first conductive feature can have the maximum lateral dimension less than 1 μm.

In one embodiment, an entire area of the bonding interface is smaller than about 100 μm². The entire area of the bonding interface can be smaller than 2 μm².

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A bonded structure comprising:
a first element having a first conductive feature and a first nonconductive region, the first conductive feature comprising a fine grain metal having an average grain size of 500 nm or less; and
a second element having a second conductive feature and a second nonconductive region,
wherein the first conductive feature is directly bonded to the second conductive feature without an intervening adhesive, and the first nonconductive region is directly bonded to the second nonconductive region without an intervening adhesive.

2. The bonded structure of claim 1, wherein the first conductive feature comprises copper.

3. The bonded structure of claim 1, wherein the grains of the first conductive feature have a maximum grain size less than 500 nm.

4. The bonded structure of claim 3, wherein the grains of the first conductive feature have the maximum grain size less than 350 nm.

5. The bonded structure of claim 4, wherein the grains of the first conductive feature have the maximum grain size less than 50 nm.

6. The bonded structure of claim 1, wherein an average grain size of grains of the second conductive feature is 500 nm or less.

7. The bonded structure of claim 1, wherein the second conductive feature comprises a coarse grain metal.

8. The bonded structure of claim 7, wherein an average grain size of grains of the second conductive feature is more than 1 micron.

9. The bonded structure of claim 1, wherein the average grain size of the fine grain metal of the first conductive feature is 350 nm or less.

10. The bonded structure of claim 9, wherein the average grain size of the fine grain metal of the first conductive feature is in a range of 10 nm to 300 nm.

11. The bonded structure of claim 1, wherein more than 95% of the grains of the first conductive feature have a grain size variation less than 10%.

12. The bonded structure of claim 1, wherein the first element further comprising a metallization layer having a conductive portion.

13. The bonded structure of claim 12, wherein the conductive portion of the metallization layer includes a metal having an average grain size in a range of 1 μm to 2 μm.

14. The bonded structure of claim 1, wherein the fine grain metal of the first conductive feature comprises nanoparticles of an inert material.

15. The bonded structure of claim 14, wherein a concentration of the nanoparticles is less than 1% of the first conductive feature.

16. The bonded structure of claim 15, wherein the concentration of the nanoparticles is less than 0.1% of the first conductive feature.

17. The bonded structure of claim 14, wherein the nanoparticles comprise one or more of silicon oxide, alumina, and titanium oxide.

18. The bonded structure of claim 1, wherein the fine grain metal comprises constituents.

19. A bonded structure comprising:
a first element having a first conductive feature and a first nonconductive region, the first conductive feature comprising a fine grain metal having constituents; and
a second element having a second conductive feature and a second nonconductive region,
wherein the first conductive feature is directly bonded to the second conductive feature without an intervening adhesive, and the first nonconductive region is directly bonded to the second nonconductive region without an intervening adhesive.

20. The bonded structure of claim 19, wherein the constituents comprise at least one of boron, indium, phosphorus, gallium, nickel, cobalt, tin, manganese, titanium, vanadium and selenium.

21. The bonded structure of claim 19, wherein the first conductive feature comprises a fine grain metal having an average grain size of 500 nm or less.

22. The bonded structure of claim 21, wherein the average grain size of the fine grain metal of the first conductive feature is in a range of 10 nm to 300 nm.

23. An interconnect structure comprising:
an element having a bonding surface, the element having a conductive feature and a nonconductive region, the conductive feature at least partially embedded in the nonconductive region, the conductive feature comprising a bottom portion and a top portion disposed over the bottom portion, the top portion positioned closer to the bonding surface of the element, the top portion having an average grain size smaller than the average grain size of the bottom portion,
wherein the average grain size of the top portion is 500 nm or less.

24. A bonded structure comprising the interconnect structure of claim 23 and a second element.

25-80. (canceled)
